(19) United States
(12) Patent Application Publication
(10) Pub. No.: US 2026/0068477 A1
(43) Pub. Date: Mar. 5, 2026

(54) DISPLAY DEVICE AND ELECTRONIC DEVICE INCLUDING THE SAME

(71) Applicant: Samsung Display Co., LTD., Yongin-si (KR)

(72) Inventors: CHANHEE PARK, Yongin-si (KR); ARUMI PARK, Yongin-si (KR); HYO-SUB SONG, Yongin-si (KR); SEUNGHUI YOO, Yongin-si (KR); JAEYOUNG JANG, Yongin-si (KR)

(21) Appl. No.: 19/246,082

(22) Filed: Jun. 23, 2025

(30) Foreign Application Priority Data
Sep. 5, 2024 (KR) 10-2024-0120590

(51) Int. Cl. H10K 59/65; G06V 40/13; H10K 59/126; H10K 59/80

(52) U.S. Cl. CPC H10K 59/65; G06V 40/1318; H10K 59/126; H10K 59/871

(57) ABSTRACT

A display device includes a display panel including a display area in which a plurality of pixels is disposed and a peripheral area surrounding at least a portion of the display area and including a pad area spaced apart from one side of the display area in a first direction, a circuit board disposed under the display panel and including a first area including a step portion and a second area spaced apart from the first area in a second direction intersecting the first direction and including a ground portion, a cover member covering the first area and the second area of the circuit board, and a fingerprint sensing module disposed under the cover member, contacting the cover member, and including a shield-can overlapping the first area of the circuit board in a plan view.

This application claims priority to Korean Patent Application No. 10-2024-0120590, filed on Sep. 5, 2024, and all the benefits accruing therefrom under 35 U.S.C. § 119, the content of which in its entirety is herein incorporated by reference.

### BACKGROUND

### 1. Field

The present disclosure relates to a display device and an electronic device including the same. More specifically, the present disclosure relates to the display device that provides visual information and the electronic device including the same.

### 2. Discussion of the Background

In the case of circuit boards, which are essential for electronic devices such as mobile phones, digital cameras, and notebook computers, which are rapidly miniaturizing and improving performance, a large number of complex electronic components are mounted in a compact space. In other words, in electronic devices such as mobile phones, digital cameras, and notebook computers, which are rapidly miniaturizing and improving performance, circuit boards (including flexible circuit boards) are essential for mounting complex mechanisms and circuits in a narrow space.

When using such electronic devices or communication devices, electromagnetic waves are generated from various components mounted on the circuit board. Since such electromagnetic waves may act as noise in the communication function of the electronic device, a shield-can made of metal that may shield the electromagnetic waves may be provided on an upper surface of the component when mounting the component on the circuit board.

However, when an impact is applied to a product including the shield-can, a problem occurs in which the shield-can is separated from the surface to which it is attached. Various problem-solving methods are being sought to solve this problem.

### SUMMARY

One aspect of the present disclosure is that it can provide a display device with improved reliability and stability.

Another aspect of the present disclosure is to provide an electronic device including the display device.

A display device according to an embodiment of the present disclosure includes a display panel including a display area in which a plurality of pixels is disposed and a peripheral area surrounding at least a portion of the display area and including a pad area spaced apart from one side of the display area in a first direction, a circuit board disposed under the display panel and including a first area including a step portion and a second area spaced apart from the first area in a second direction intersecting the first direction and including a ground portion, a cover member covering the first area and the second area of the circuit board, and a fingerprint sensing module disposed under the cover member, contacting the cover member, and including a shield-can overlapping the first area of the circuit board in a plan view.

In an embodiment, the cover member may include a body portion, a first protrusion protruding from the body portion in a direction opposite to the first direction, and a second protrusion protruding from the body portion in the direction opposite to the first direction and spaced apart from the first protrusion in the second direction.

In an embodiment, the first protrusion of the cover member may overlap the first area in the plan view, and the second protrusion of the cover member may overlap the second area in the plan view.

In an embodiment, the fingerprint sensing module may further include a fingerprint sensing part configured to detect a user's fingerprint, a sensing driving element configured to transmit a signal transmitted from the fingerprint sensing part to the circuit board, and a sensing circuit film configured to connect the fingerprint sensing part and the sensing driving element.

In an embodiment, the display area of the display panel may include a fingerprint sensing area where the user's fingerprint contacts.

In an embodiment, wherein the fingerprint sensing part may overlap the fingerprint sensing area of the display panel in the plan view.

In an embodiment, the display device may further include a cover panel disposed under the display panel.

In an embodiment, the fingerprint sensing module may be disposed under the cover panel in a cross-sectional view.

In an embodiment, an opening may be defined in the cover panel and at least partially overlap the fingerprint sensing area in the plan view.

In an embodiment, the fingerprint sensing part of the fingerprint sensing module may overlap the opening of the cover panel in the plan view.

In an embodiment, the sensing driving element may overlap the first area of the circuit board in the plan view.

In an embodiment, the shield-can may cover the sensing driving element of the fingerprint sensing module.

In an embodiment, the display device may further include an adhesive member disposed between the first protrusion of the cover member and the sensing driving element of the fingerprint sensing module.

In an embodiment, the display device may further include a display driving chip disposed in the pad area of the display panel, and the cover member may cover the display driving chip.

In an embodiment, the circuit board may be electrically connected to the cover member.

In an embodiment, the display device may further include a connection circuit board disposed in the pad area of the display panel, and the connection circuit board may connect the display panel and the circuit board.

In an embodiment, the connecting circuit board may be bent around a bending axis extending parallel to the second direction.

In an embodiment, the cover member may include a first insulating layer, a conductive layer disposed on the first insulating layer; and a second insulating layer disposed on the conductive layer.

A display device according to another embodiment of the present disclosure includes a display panel including a display area in which a plurality of pixels is disposed and a peripheral area surrounding at least a part of the display area and including a pad area spaced apart from one side of the display area in a first direction, a circuit board disposed under the display panel, including a first area including a step portion and a second area spaced apart from the first area in a second direction intersecting the first direction and including a ground portion, and a cover member covering the first area and the second area and including a body portion, a first protrusion protruding from the body portion in a direction opposite to the first direction, and a second protrusion protruding from the body portion in a direction opposite to the first direction and spaced apart from the first area in the second direction.

In an embodiment, the display device may further include a fingerprint sensing module disposed under the display panel and including a fingerprint sensing part configured to detect a user's fingerprint, a sensing driving element configured to transmit a signal transmitted from the fingerprint sensing part to the circuit board, a sensing circuit film configured to connect the fingerprint sensing part and the sensing driving element, and a shield-can disposed under the cover member, contacting the cover member, overlapping the first area of the circuit board in a plan view, and covering the sensing driving element.

An electronic device according to an embodiment of the present disclosure includes a display device and a processor configured to drive the display device, and the display device includes a display panel including a display area in which a plurality of pixels is disposed and a peripheral area surrounding at least a portion of the display area and including a pad area spaced apart from one side of the display area in a first direction, a circuit board disposed under the display panel and including a first area including a step portion and a second area spaced apart from the first area in a second direction intersecting the first direction and including a ground portion, a cover member covering the first area and the second area of the circuit board, and a fingerprint sensing module disposed under the cover member, contacting the cover member, and including a shield-can overlapping the first area of the circuit board in a plan view. A display device according to an embodiment of the present disclosure may include a display panel including a display area in which a plurality of pixels is disposed and a peripheral area surrounding at least a portion of the display area and including a pad area spaced apart from one side of the display area in a first direction, a circuit board disposed under the display panel and including a first area including a step portion and a second area spaced apart from the first area in a second direction intersecting the first direction and including a ground portion, a cover member covering the first area and the second area of the circuit board, and a fingerprint sensing module disposed under the cover member, contacting the cover member, and including a shield-can overlapping the first area of the circuit board in a plan view.

Accordingly, the shield-can may not be attached to the step portion of the circuit board, but may be directly attached to the first protrusion of the cover member having a flat surface. That is, the shield-can may have a greater adhesive force when attached to the cover member having a flat surface than when attached to the step portion. As a result, even if there is an external impact, etc., the shield-can remain adhered without falling off from the cover member, so that the reliability and stability of the display device may be effectively improved.

### BRIEF DESCRIPTION OF THE DRAWINGS

The accompanying drawings, which are included to provide a further understanding of the invention and are incorporated in and constitute a part of this specification, illustrate embodiments of the invention together with the description.

FIG. 1 is a perspective view showing a display device according to an embodiment of the present disclosure.

FIG. 2 is an exploded perspective view of the display device of FIG. 1.

FIG. 3 is an exploded perspective view of the window module and the display module of FIG. 2.

FIG. 4 is a perspective view showing the display module and the cover member of FIG. 3.

FIG. 5 is a cross-sectional view showing a side of the display device of FIG. 3.

FIG. 6 is a cross-sectional view showing an embodiment of the display panel of FIG. 3.

FIGS. 7 and 8 are rear views showing an embodiment of the rear surface of FIG. 3.

FIG. 9 is a cross-sectional view taken along the line I-I′ of FIG. 7.

FIG. 10 is a cross-sectional view showing an embodiment of the fingerprint sensing part of FIG. 7.

FIG. 11 is a block-diagram showing an electronic device according to an embodiment of the present disclosure.

FIG. 12 is schematic views of the electronic devices according to various embodiments of FIG. 11.

### DETAILED DESCRIPTION

Regarding embodiments of the present disclosure disclosed in this text, specific structural and functional descriptions are merely illustrative for a purpose of explaining the embodiments of the present disclosure, and the embodiments of the present disclosure may be implemented in various forms and should not be construed as limited to the embodiments described in.

Since the present disclosure may be subject to various changes and may have various forms, specific embodiments will be illustrated in the drawings and described in detail in the text. However, this is not intended to limit the present disclosure to a specific disclosed form, and should be understood to include all changes, equivalents, and substitutes included in the spirit and technical scope of the present disclosure.

Terms such as first, second, etc. may be used to describe various components, but the components should not be limited by the terms. The above terms may be used for a purpose of distinguishing one component from another component. For example, a first component may be referred to as a second component, and similarly, the second component may be referred to as a first component without departing from the scope of the present disclosure.

It will be understood that when an element is referred to as being “connected” or “coupled” to another element, it may be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for a purpose of describing particular example embodiments only and is not intended to be limiting of the present inventive concept. As used herein, the singular forms “a,” “an” and “the” are intended to include plural forms as well, unless the context clearly indicates otherwise. It will be further understood that the terms “comprises” and/or “comprising,” when used in this specification, specify a presence of stated features, integers, steps, operations, elements, and/or components, but do not preclude the presence or addition of one or more other features, integers, steps, operations, elements, components, and/or groups thereof.

Terms such as “below”, “at the bottom”, “lower”, “below”, “above”, “on top”, “on the top”, “on”, etc. is used to explain a relationship between components shown in the drawings. The terms are relative concepts and are explained based on the direction indicated in the drawings.

Unless otherwise defined, all terms (including technical and scientific terms) used herein have a same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. Same reference numerals are used for same components in the drawings, and redundant descriptions of same components will be omitted.

In this specification, a plane may be defined by a first direction D1 and a second direction D2 that intersects the first direction D1. For example, the second direction D2 may be perpendicular to the first direction D1. In addition, a third direction D3 may be a normal direction of the plane. That is, the third direction D3 may be perpendicular to the plane formed by the first direction D1 and the second direction D2.

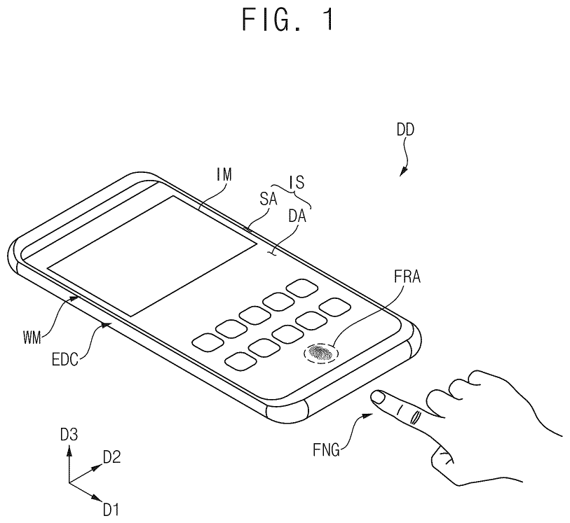

FIG. 1 is a perspective view showing a display device according to an embodiment of the present disclosure.

Referring to FIG. 1, a display device DD may display images IM toward a third direction D3 on a display surface IS parallel to each of a first direction D1 and a second direction D2. The display surface IS of the display device DD may include a display area DA and a peripheral area SA.

The display area DA may be an area where images IM are displayed. A user may recognize the images IM through the display area DA. In a present embodiment, the display area DA may include a square shape with rounded corners. However, the embodiment of the present disclosure is not necessarily limited thereto. The display area DA may have various shapes in a plan view. As used herein, the “plan view” is a view in a thickness direction (i.e., third direction DR3) of the display device DD.

The peripheral area SA may surround the display area DA. The peripheral area SA may be placed adjacent to only one side of the display area DA, or may be omitted. However, the embodiment of the present disclosure is not necessarily limited thereto. The peripheral area SA may have various shapes in a plan view.

The display device DD may detect a user's fingerprint FNG transmitted from the outside. Accordingly, the display device DD may include a fingerprint sensing area FRA for sensing the user's fingerprint FNG on the display surface IS. A user of the display device DD may contact the fingerprint FNG on the fingerprint sensing area FRA. However, the embodiment of the present disclosure is not necessarily limited thereto. The fingerprint sensing area FRA may be provided in the peripheral area SA, in an entire area of the display area DA, or in an entire area of the display surface IS.

The user's fingerprint FNG may include a surface condition of the user's hand, such as surface uniformity, surface curvature shape, shape of the user's blood vessels, etc. However, the embodiment of the present disclosure is not necessarily limited thereto.

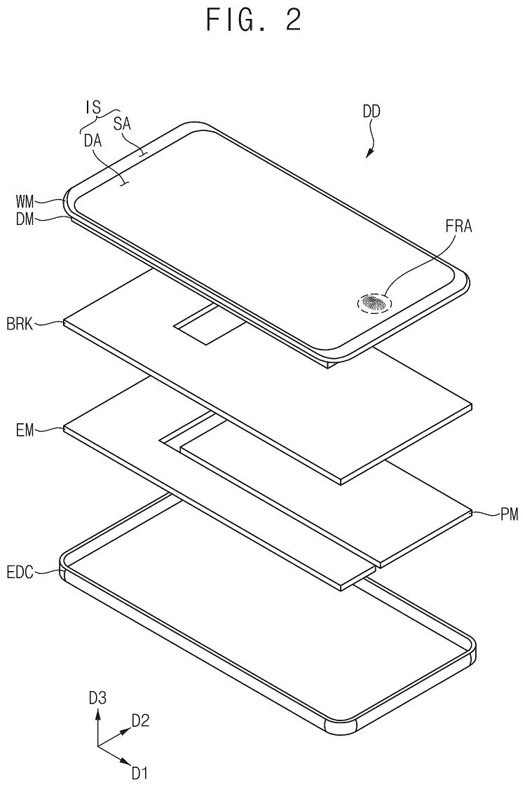

FIG. 2 is an exploded perspective view of the display device of FIG. 1.

Referring to FIGS. 1 and 2, the display device DD may include a window module WM, a display module DM, an electronic module EM, a power supply module PM, a bracket BRK, and an external case EDC.

The window module WM may be disposed on an upper surface of the display device DD. In an embodiment, the window module WM may be ultrathin glass (UTG). For example, the window module WM may include soda-lime glass, alkali aluminosilicate glass, borosilicate glass, lithium aluminosilicate glass, etc. These may be used alone or in combination with each other. However, the window module WM of the present disclosure is not necessarily limited thereto and may include various materials such as plastic.

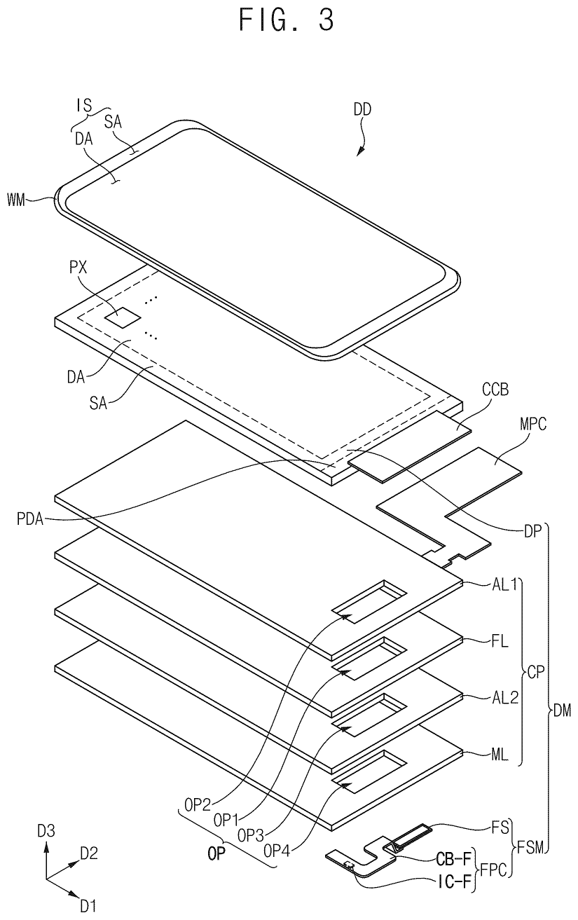

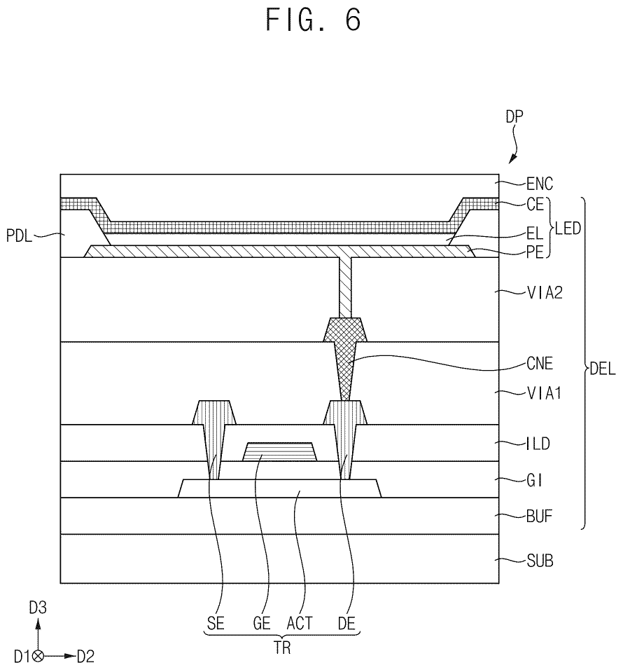

The display module DM may be disposed below the window module WM. The display module DM may provide visual information to a user of the display device DD. Light provided from the display module DM may pass through the window module WM and provide the images IM, etc. to users of the display device DD. The display module DM will be described in detail later with reference to FIGS. 3 and 6.

The bracket BRK may be disposed under the display module DM. The bracket BRK may be combined with the external case EDC to divide the internal space of the display device DD. The bracket BRK provides a space in which other components may be disposed. In addition, the bracket BRK may support the display module DM so that the display module DM is fixed without shaking. For example, the bracket BRK may include metal or plastic. In FIG. 2, one bracket is illustrated as an example, but the display device DD may include a plurality of brackets.

The electronic module EM may be disposed under the bracket BRK. The electronic module EM may be electrically connected to the display module DM. The display module DM may receive information about the images IM to be displayed through the electronic module EM, or may provide the detected fingerprint FNG information to the electronic module EM and provide the processed information based on the information to the user.

The power supply module PM may be disposed under the bracket BRK. The power supply module PM may be disposed on a same layer as the electronic module EM. The power supply module PM may supply power for an overall operation of the display device DD. The power supply module PM may include a conventional battery module.

The outer case EDC may cover the display module DM, the bracket BRK, the electronic module EM, and the power supply module PM. The outer case EDC may be coupled to the bracket BRK, the display module DM, and/or the window module WM. That is, the outer case EDC may form an exterior of the display device DD together with the window module WM. In FIG. 2, the outer case EDC is exemplarily illustrated as consisting of one body, but the outer case EDC may include a plurality of bodies that are assembled together. The outer case EDC may include a plurality of frames and/or plates made of glass, plastic, and metal. These may be used alone or in combination with each other. However, the embodiment of the present disclosure is not necessarily limited thereto.

FIG. 3 is an exploded perspective view of the window module and the display module of FIG. 2.

Referring to FIGS. 2 and 3, the display module DM may include a display panel DP, a cover panel CP, and a fingerprint sensing module FSM.

The peripheral area SA of the display device DD may include a pad area PDA. Specifically, the pad area PDA may be disposed on one side of the peripheral area SA and may be placed apart from the display area DA in the first direction D1. However, the embodiment of the present disclosure is not necessarily limited thereto.

A plurality of pixels PX may be disposed in the display area DA of the display panel DP. The pixels PX may be disposed along the first direction D1 and/or the second direction D2. The display panel DP may provide visual information, etc. to a user of the display device DD by an input signal. A cross-sectional shape of the display panel DP will be described later with reference to FIG. 6.

A connection circuit board CCB may be disposed on the pad area PDA of the display panel DP. One side of the connection circuit board CCB may be attached to the display panel DP to transmit and receive signals with the display panel DP. In addition, the other side of the connection circuit board CCB may be connected to a circuit board MPC that drives the display panel DP. Accordingly, the circuit board MPC may transmit and receive signals with the display panel DP by the connection circuit board CCB.

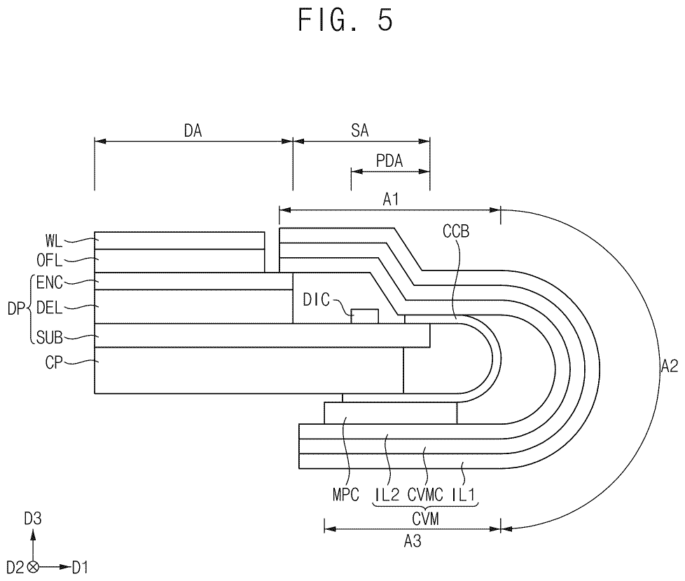

The circuit board MPC may be electrically connected to an electronic component (e.g., a timing control unit). The circuit board MPC may generate a scan control signal, a data control signal, and image data by using an image signal and a plurality of timing signals received from the electronic component. The generated scan control signal, the data control signal, and the image data may be provided to a driving chip (e.g., the driving chip DIC of FIG. 5) through the circuit board MPC.

The cover panel CP may be disposed under the display panel DP. The cover panel CP may have a shape substantially same as the display panel DP in a plan view. The cover panel CP may protect the display panel DP from external impact or the inflow of foreign substances. As illustrated in FIG. 3, the cover panel CP may include a plurality of layers. For example, the cover panel CP may include a first adhesive layer AL1, a functional layer FL, a second adhesive layer AL2, and a metal layer ML.

The first adhesive layer AL1 may be disposed under the display panel DP. The first adhesive layer AL1 may attach the display panel DP and the functional layer FL. The first adhesive layer AL1 may include a transparent adhesive material. For example, the first adhesive layer AL1 may include at least one of an optically clear resin (OCR), an optically clear adhesive (OCA), a double-sided tape, and a pressure-sensitive adhesive (PSA). These may be used alone or in combination with each other. However, the embodiments of the present disclosure are not necessarily limited thereto.

The functional layer FL may be disposed under the first adhesive layer AL1. The functional layer FL may include a cushion layer. The functional layer FL may easily absorb impact, etc. transmitted from an outside of the display device DD. That is, the functional layer FL may improve an impact resistance of the display device DD. For example, the functional layer FL may include a synthetic resin foam including a matrix member and a plurality of pores. However, the embodiment of the present disclosure is not necessarily limited thereto. In addition to the cushion layer, the functional layer FL may also include other functional layers such as a light-shielding layer.

The second adhesive layer AL2 may be disposed under the functional layer FL. The second adhesive layer AL2 may adhere the metal layer ML and the functional layer FL. The second adhesive layer AL2 may include substantially same material as the first adhesive layer AL1. For example, the second adhesive layer AL2 may include at least one of an optically clear resin (OCR), an optically clear adhesive (OCA), a double-sided tape, and a pressure-sensitive adhesive (PSA).

The metal layer ML may be disposed under the second adhesive layer AL2. The metal layer ML may perform a heat dissipation function. That is, the metal layer ML may discharge heat generated from the display panel DP or the like to the outside. The metal layer ML may include a metal material having high thermal conductivity. For example, the metal layer ML may include copper, aluminum, etc. These may be used alone or in combination with each other. However, the embodiments of the present disclosure are not necessarily limited thereto.

In an embodiment, an opening OP may be defined in each of the first adhesive layer AL1, the functional layer FL, the second adhesive layer AL2, and the metal layer ML. The opening OP may include first to fourth openings OP1, OP2, OP3, and OP4. Specifically, the first opening OP1 may be defined in the first adhesive layer AL1, the second opening OP2 may be defined in the functional layer FL, the third opening OP3 may be defined in the second adhesive layer AL2, and the fourth opening OP4 may be defined in the metal layer ML. The first to fourth openings OP1, OP2, OP3, and OP4 may overlap in a plan view. Accordingly, a fingerprint sensing part FS of the fingerprint sensing module FSM may be attached to a lower surface of the display panel DP through the opening OP.

The fingerprint sensing module FSM may be disposed under the cover panel CP. The fingerprint sensing module FSM may include the fingerprint sensing part FS and a sensing circuit board FPC. The fingerprint sensing module FSM may recognize the fingerprint (e.g., the fingerprint FNG of FIG. 1) of the user of the display device DD and transmit a signal to the circuit board MPC. The display panel DP may be driven by a signal of the fingerprint (e.g., the fingerprint FNG of FIG. 1) transmitted from the fingerprint sensing module FSM.

The sensing circuit board FPC of the fingerprint sensing module FSM may include a sensing circuit film CB-F and a sensing driving element IC-F. The sensing circuit film CB-F may be connected to the fingerprint sensing part FS. For example, the sensing circuit film CB-F may be connected to the fingerprint sensing part FS via an adhesive member such as an anisotropic conductive film, or may be coupled to the fingerprint sensing part FS via a separate connector. The sensing circuit film CB-F may be electrically connected to the circuit board MPC.

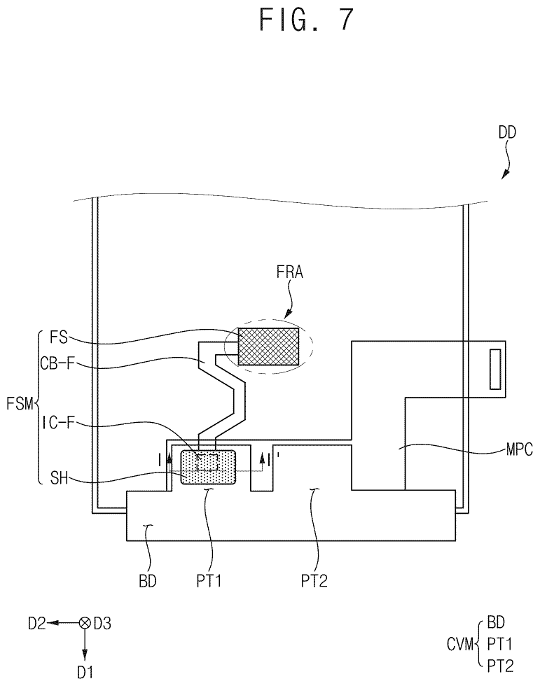

The sensing driving element IC-F may be mounted on the sensing circuit film CB-F. The sensing driving element IC-F may be electrically connected to the fingerprint sensing part FS by being connected to signal lines of the sensing circuit film CB-F. The sensing driving element IC-F may receive an electrical signal generated by a user's fingerprint (e.g., the fingerprint FNG of FIG. 1) from the fingerprint sensing part FS and process it. An arrangement of the fingerprint sensing module FSM will be described later with reference to FIGS. 7 and 8.

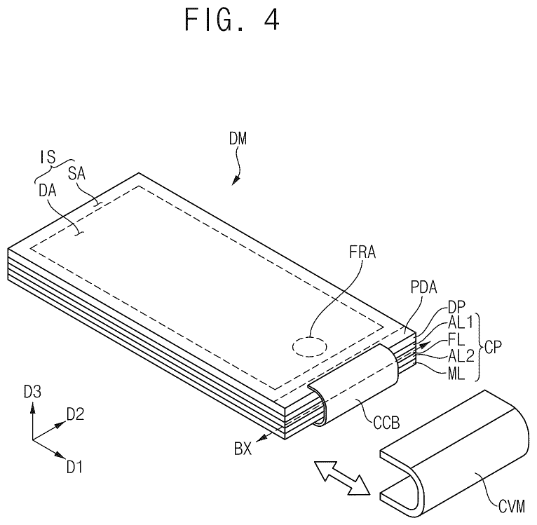

FIG. 4 is a perspective view showing the display module and the cover member of FIG. 3. FIG. 5 is a cross-sectional view showing a side of the display device of FIG. 3.

Referring to FIGS. 3 and 4, a cover member CVM may cover one side of the display module DM. Specifically, the cover member CVM may cover the peripheral area SA of the display module DM. In FIGS. 4 and 5, the cover member CVM is illustrated as having a ‘U’ shape in a cross-sectional view and covering an upper and lower surfaces of the display module DM, but the embodiment of the present disclosure is not necessarily limited thereto. The cover member CVM may cover only one of an upper or lower surfaces of the display module DM.

Referring further to FIG. 5, the display device DD may include the cover panel CP, the display panel DP, an optical function layer OFL, the window module WM, the driving chip DIC, the connection circuit board CCB, the circuit board MPC, and the cover member CVM. The display panel DP may include a substrate SUB, a display element layer DEL, and an encapsulation layer ENC. Since the cover panel CP, the display panel DP, the window module WM, the connection circuit board CCB, and the circuit board MPC have been described with reference to FIG. 2, overlapping content may be omitted or simplified.

The optical function layer OFL may be disposed on the display panel DP. That is, the optical function layer OFL may be a layer disposed on the display panel DP and performing an optical function of controlling light emitted from the display panel DP.

In an embodiment, the optical function layer OFL may be a polarizing layer. For example, the optical function layer OFL may polarize light incident from an outside onto the display panel DP. The optical function layer OFL may be elongated in one direction. An elongation direction of the optical function layer OFL may be an absorption axis, and a direction perpendicular to the elongation direction may be a transmission axis. However, the optical function layer OFL according to embodiments of the present disclosure is not necessarily limited thereto, and the optical function layer OFL may not include a polarizing layer and may include a color filter. In other words, the display device DD may have a structure that does not include a polarizing layer.

The cover member CVM may cover the circuit board PCB and the driving chip DIC. One end of the cover member CVM may be attached to the sealing layer ENC of the display panel DP, and the other end disposed opposite the one end of the cover member CVM may be attached to the circuit board MPC or the cover panel CP. That is, the cover member CVM may protect the circuit board PCB and the driving chip DIC from external impact or foreign matter inflow.

In an embodiment, the cover member CVM may include three layers. For example, the cover member CVM may include a first insulating layer IL1, a conductive layer CVMC, and a second insulating layer IL2. The conductive layer CVMC may be disposed on the first insulating layer IL1, and the second insulating layer IL2 may be disposed on the conductive layer CVMC. However, the embodiment of the present disclosure is not necessarily limited thereto. In another embodiment, the cover member CVM may have a single-layer structure including one insulating layer.

For example, the first insulating layer IL1 and the second insulating layer IL2 may include an insulating material including polyimide (Pl) or polyethylene terephthalate (PET).

The circuit board MPC may be electrically connected to the cover member CVM, and static electricity, etc. generated in the circuit board MPC may be discharged through the conductive layer CVMC of the cover member CVM. That is, the cover member CVM may not only physically protect the display panel DP, but may also discharge static electricity, etc. generated in the circuit board MPC to prevent damage to the circuit board MPC. The above-described conductive layer CVMC may include aluminum (Al), gold (Au), silver (Ag), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy containing aluminum, an alloy containing silver, an alloy containing copper, an alloy containing molybdenum, etc. These may be used alone or in combination with each other. However, the embodiment of the present disclosure is not necessarily limited thereto.

In an embodiment, as illustrated in FIG. 4, the cover member CVM may be bent about a bending axis BX. The bending axis BX may be a virtual axis extending parallel to the second direction D2 intersecting the first direction D1. That is, the cover member CVM may be bent about the bending axis BX extending along the second direction D2. Accordingly, the cover member CVM may cover at least a portion of upper and lower surfaces of the substrate SUB.

FIG. 6 is a cross-sectional view showing an embodiment of the display panel of FIG. 3.

Referring to FIGS. 1, 3, 5, and 6, the display panel DP may include the substrate SUB, the display element layer DEL, and the encapsulation layer ENC. The display element layer DEL may include a buffer layer BUF, a gate insulating layer GI, a transistor TR, an interlayer-insulating layer ILD, a connection electrode CNE, a first via-layer VIA1, a second via-layer VIA2, a light emitting diode LED, and a pixel defining layer PDL.

The transistor TR may include an active layer ACT, a gate electrode GE, a source electrode SE, and a drain electrode DE. The light emitting diode LED may include a pixel electrode PE, an emitting layer EL, and a common electrode CE.

The substrate SUB may include a glass substrate, a metal substrate, a plastic substrate, etc. However, the embodiments of the present disclosure are not necessarily limited thereto, and the substrate SUB may be an inorganic layer, an organic layer, or a composite material layer.

The buffer layer BUF may be disposed on the substrate SUB. The buffer layer BUF may prevent impurities such as oxygen and moisture from penetrating into an upper portion of the substrate SUB through the substrate SUB. The buffer layer BUF may include an inorganic insulating material.

The active layer ACT may be disposed on the buffer layer BUF. The active layer ACT may include an oxide semiconductor, a silicon semiconductor, an organic semiconductor, etc. For example, the oxide semiconductor may include at least one oxide from among indium (In), gallium (Ga), tin (Sn), zirconium (Zr), vanadium (V), hafnium (Hf), cadmium (Cd), germanium (GE), chromium (Cr), titanium (Ti), and zinc (Zn). The silicon semiconductor may include amorphous silicon, polycrystalline silicon, etc. The active layer ACT may include a source region, a drain region, and a channel region positioned between the source region and the drain region.

The gate insulating layer GI may be disposed on the buffer layer BUF. Specifically, the gate insulating layer GI may cover the active layer ACT on the buffer layer BUF. The gate insulating layer GI may include an inorganic insulating material. In an embodiment, the gate insulating layer GI may be disposed entirely over the display area DA and the peripheral area SA. In an embodiment, the gate insulating layer GI may be disposed only under the gate electrode GE.

The gate electrode GE may be disposed on the gate insulating layer GI. The gate electrode GE may overlap at least a portion of the channel area of the active layer ACT in a plan view. The gate electrode GE may include a conductive material such as a metal, an alloy, a conductive metal nitride, a conductive metal oxide, or a transparent conductive material. Examples of the conductive material that may be used for the gate electrode GE include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy containing aluminum, an alloy containing silver, an alloy containing copper, an alloy containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc, oxide (IZO), etc. These may be used alone or in combination with each other. Optionally, the gate electrode GE may have a single-layer structure or a multi-layer structure including a plurality of conductive layers.

The interlayer-insulating layer ILD may be disposed on the gate electrode GE. Specifically, the interlayer-insulating layer ILD may be disposed on the gate insulating layer GI and cover the gate electrode GE on the gate insulating layer GI. The interlayer-insulating layer ILD may include an inorganic insulating material. In an embodiment, the interlayer-insulating layer ILD may be disposed entirely on the display area DA and the peripheral area SA.

The source electrode SE and the drain electrode DE may be disposed on the interlayer-insulating layer ILD. Each of the source electrode SE and the drain electrode DE may be connected to the active layer ACT. For example, the source electrode SE may be in contact with the source region of the active layer ACT, and the drain electrode DE may be in contact with the drain region of the active layer ACT. Each of the source electrode SE and the drain electrode DE may include a conductive material. The active layer ACT, the gate electrode GE, the source electrode SE, and the drain electrode DE may form the transistor TR.

The first via-layer VIA1 may be disposed on the source electrode SE and the drain electrode DE. Specifically, the first via-layer VIA1 may be disposed on the interlayer-insulating layer ILD and may cover the source electrode SE and the drain electrode DE on the interlayer-insulating layer ILD. The first via-layer VIA1 may include an organic insulating material. In an embodiment, the first via-layer VIA1 may be disposed only the display area DA and on a portion of the peripheral area SA adjacent to the display area DA.

The connection electrode CNE may be disposed on the first via-layer VIA1. The connection electrode CNE may transmit a signal transmitted from the transistor TR to the light emitting diode LED. The connection electrode CNE may include a metal, an alloy, a metal nitride, a conductive metal oxide, a transparent conductive material, etc. These may be used alone or in combination with each other. However, the embodiment of the present disclosure is not necessarily limited thereto.

The second via-layer VIA2 may be disposed on the connection electrode CNE. Specifically, the second via-layer VIA2 may be disposed on the first via-layer VIA1 and may cover the connection electrode CNE. The second via-layer VIA2 may include substantially a same material as the first via-layer VIA1.

The pixel electrode PE may be disposed on the second via-layer VIA2. The pixel electrode PE may include a conductive material. The pixel electrode PE may be connected to the drain electrode DE through the connection electrode CNE. Accordingly, the pixel electrode PE may be electrically connected to the transistor TR.

The pixel defining layer PDL may be disposed on the pixel electrode PE. For example, the pixel defining layer PDL may expose at least a portion of the pixel electrode PE. The pixel defining layer PDL may include an inorganic insulating material or an organic insulating material.

The light-emitting layer EL may be disposed on the pixel electrode PE. In an embodiment, the light-emitting layer EL may be disposed within an opening defined by the pixel defining layer PDL. That is, the light-emitting layer EL may be surrounded by the pixel defining layer PDL. In an embodiment, the light-emitting layer EL may also be disposed on the pixel defining layer PDL. The light-emitting layer EL may include at least one of an organic light-emitting material and/or a quantum dot. However, the embodiment of the present disclosure is not necessarily limited thereto.

The common electrode CE may be disposed on the light-emitting layer EL. The common electrode CE may also be disposed on the pixel defining layer PDL. That is, the common electrode CE may be disposed continuously on the light-emitting layer EL and the pixel defining layer PDL. The common electrode CE may include a conductive material. The light-emitting layer EL may emit light based on a voltage difference between the pixel electrode PE and the common electrode CE.

The encapsulation layer ENC may be disposed on the common electrode CE. The encapsulation layer ENC may include at least one inorganic encapsulation layer and at least one organic encapsulation layer. In an embodiment, the inorganic encapsulation layer and the organic encapsulation layer may be alternately disposed. For example, the organic encapsulation layer may include a polymer cured material such as polyacrylate, epoxy resin, silicone resin, etc. For example, the inorganic thin film may include silicon oxide, silicon nitride, silicon carbide, aluminum oxide, tantalum oxide, hafnium oxide, zirconium oxide, titanium oxide, etc.

FIGS. 7 and 8 are rear views showing an embodiment of the rear surface of FIG. 3. Specifically, FIG. 8 is a rear view showing the fingerprint sensing module FSM and the cover member CVM of FIG. 7 separated from the circuit board MPC.

Referring to FIGS. 7 and 8, the circuit board MPC, the cover member CVM, and the fingerprint sensing module FSM may be disposed on a rear surface of the display device DD.

The circuit board MPC may include a first area A1 including a step portion ST and a second area A2 including a ground portion CT. The first area A1 may be spaced apart from the second area A2 along the second direction D2.

The step portion ST of the first area A1 illustrated in FIG. 8 may mean a groove concavely dug along the third direction D3 in the circuit board MPC. For example, the step portion ST of the first area A1 may be a concave area defined in a plan view of the circuit board MPC. However, the embodiment of the present disclosure is not necessarily limited thereto. The step portion ST may also include a portion (i.e., a convex area) protruding in the opposite direction of the third direction D3 in the circuit board MPC.

The ground portion CT of the second area A2 may be a passage through which static electricity, etc. generated from the circuit board MPC is discharged and escaped. Specifically, static electricity generated from the circuit board MPC may escape through the cover member CVM in contact with the ground portion CT. Accordingly, damage to the circuit board MPC due to the static electricity may be prevented or reduced.

In an embodiment, the ground portion CT may be defined not only in the second area A2 but also in the first area A1. That is, an area may be defined not only the step portion ST but also the cover member CVM that may be grounded with in the first area A1. Accordingly, the static electricity generated from the circuit board MPC may be discharged not only through the ground portion CT defined in the second area A2, but also through the first area A1. That is, as illustrated in FIG. 8, since the static electricity is discharged through the first area A1 and the second area A2, a discharge performance of the cover member CVM may be improved.

In an embodiment, the cover member CVM may include a body portion BD, a first protrusion PT1, and a second protrusion PT2. For example, the first protrusion PT1 may protrude from the body portion BD in a direction opposite to the first direction D1. The second protrusion PT2 may protrude from the body portion BD in a direction opposite to the first direction D1 and may be spaced apart from the first protrusion PT1 in a direction opposite to the second direction D2. However, the embodiment of the present disclosure is not necessarily limited thereto. The cover member CVM may include three or more protrusions.

In an embodiment, the first protrusion PT1 may overlap the first area A1 of the circuit board MPC in a plan view. The first protrusion PT1 may cover the step portion ST of the first area A1. The second protrusion PT2 may overlap the second area A2 of the circuit board MPC in a plan view. The second protrusion PT2 may cover the ground portion CT of the second area A2.

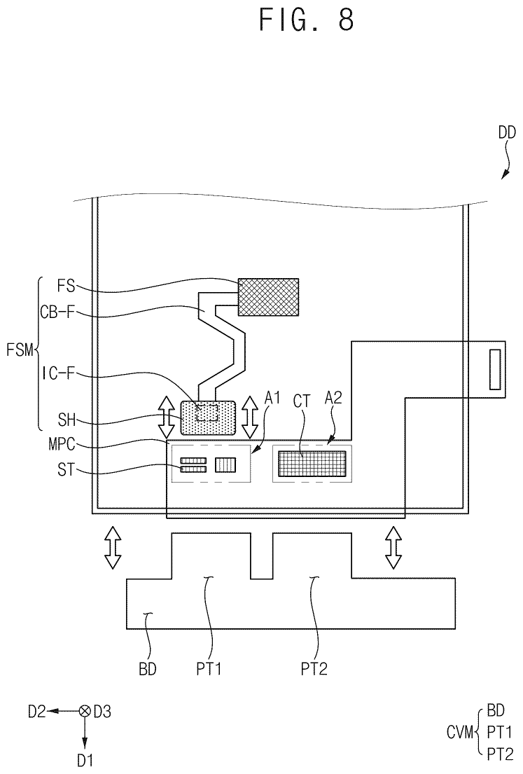

Accordingly, the shield-can SH may not be directly attached to the step portion ST of the circuit board MPC, but may be directly attached to the first protrusion PT1 of the cover member CVM having a flat surface (e.g., through the first adhesive member AD1. See FIG. 9). That is, the shield-can SH may have a greater adhesive force when attached to the cover member CVM having a flat surface than when attached to the step portion ST. As a result, even if there is an external impact, the shield-can SH may not fall off from the cover member CVM and may remain adhered, so that the reliability and stability of the display device DD may be effectively improved.

The fingerprint sensing part FS of the fingerprint sensing module FSM may overlap the fingerprint sensing area FRA in a plan view. That is, since the fingerprint sensing part FS overlaps the fingerprint sensing area FRA in a plan view, the user's fingerprint of the display device DD may be recognized by the fingerprint sensing part FS in the fingerprint sensing area FRA.

The fingerprint sensing part FS may be electrically connected to the sensing circuit film CB-F. That is, wirings disposed inside the sensing circuit film CB-F and the fingerprint sensing part FS are connected, so that the user's signal, etc. detected by the fingerprint sensing part FS may be transmitted to the sensing driving element IC-F through the sensing circuit film CB-F.

The sensing driving element IC-F may overlap the first area A1 of the circuit board MPC in a plan view. The user's signal, etc. transmitted to the sensing driving element IC-F may be transmitted to the circuit board MPC. The circuit board MPC may analyze the user's signal, etc. and transmit a driving signal, etc. to the display panel (e.g., the display panel DP of FIG. 3), etc. For example, the driving signal may be a signal for turning on the power of the display device DD in response to the fingerprint (e.g., the fingerprint FNG of FIG. 1). However, the embodiment of the present disclosure is not necessarily limited thereto.

The sensing driving element IC-F of the fingerprint sensing module FSM may be covered by a shield-can SH. That is, as illustrated in FIG. 7, the sensing driving element IC-F may be disposed on the cover member CVM, and the shield-can SH may cover the sensing driving element IC-F. A cross-sectional view of the shield-can SH covering the sensing driving element IC-F will be described later with reference to FIG. 9.

The shield-can SH may prevent electromagnetic waves generated from the circuit board MPC etc. from being transmitted to the sensing driving element IC-F. In addition, the shield-can SH may protect the sensing driving element IC-F from external impact or foreign matter inflow. The shield-can SH may be composed integrally with the sensing driving element IC-F. That is, the shield-can SH may be composed integrally with the fingerprint sensing module FSM through soldering, etc. However, the embodiment of the present disclosure is not necessarily limited thereto.

Information about the fingerprint sensing module FSM may be written on an upper surface of the shield-can SH. The product name, model name, manufacturer name, serial number, operating conditions, etc. may be written on an upper surface of the shield-can SH. However, the embodiment of the present disclosure is not necessarily limited thereto.

FIG. 9 is a cross-sectional view taken along the line I-I′ of FIG. 7.

Referring to FIGS. 7 and 9, the sensing driving element IC-F of the fingerprint sensing module FSM may be disposed on the first protrusion PT1 of the cover member CVM in a cross-sectional view. Specifically, a first adhesive member AD1 may be disposed between the sensing driving element IC-F and the first protrusion PT1 to adhere the sensing driving element IC-F and the first protrusion PT1. A signal transmitted to the sensing driving element IC-F may be transmitted to the circuit board MPC through the first protrusion PT1 of the cover member CVM. The first adhesive member AD1 may be conductive. Further, the shield-can SH may not be directly attached to the step portion ST of the circuit board MPC, but may be directly attached to the first protrusion PT1 of the cover member CVM having a flat surface through the first adhesive member AD1. See FIG. 9. That is, the shield-can SH may have a greater adhesive force when attached to the cover member CVM having a flat surface than when attached to the step portion ST.

In an embodiment, the shield-can SH of the fingerprint sensing module FSM may cover the sensing driving element IC-F. Since the shield-can SH covers the sensing driving element IC-F, the shield-can SH may protect the sensing driving element IC-F from external impact or static electricity generation.

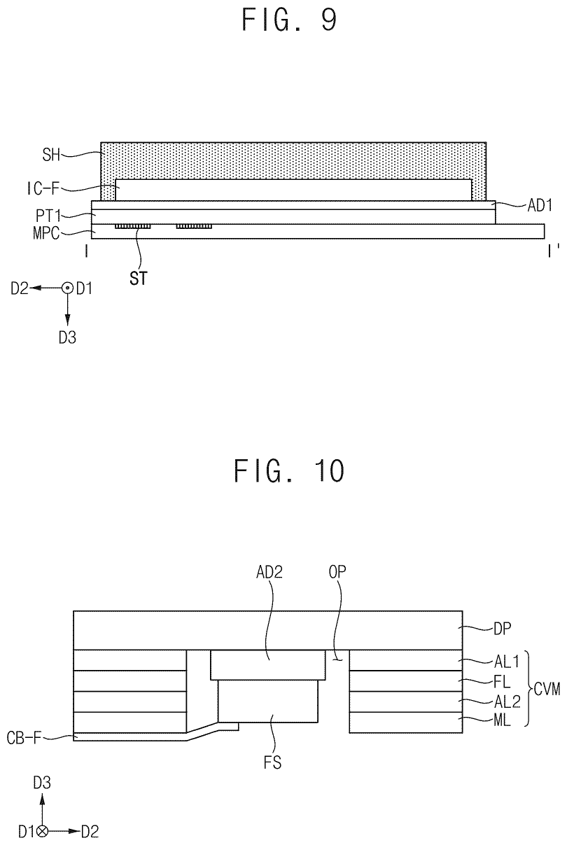

FIG. 10 is a cross-sectional view showing an embodiment of the fingerprint sensing part of FIG. 7.

Referring to FIGS. 7 and 10, the fingerprint sensing part FS may be disposed under the display panel DP. The fingerprint sensing part FS may be attached to the display panel DP by a second adhesive member AD2. The second adhesive member AD2 may include at least one of an optical transparent resin (OCR), an optical transparent adhesive (OCA), a double-sided tape, and a pressure-sensitive adhesive (PSA). These may be used alone or in combination with each other. However, the embodiment of the present disclosure is not necessarily limited thereto. Since the second adhesive member AD2 is transparent, the user's fingerprint (e.g., the fingerprint FNG of FIG. 1) may be accurately transmitted to the fingerprint sensing part FS.

Since the fingerprint sensing part FS is disposed under the display panel DP, the fingerprint sensing part FS may recognize the user's fingerprint (e.g., the fingerprint FNG of FIG. 1) that comes into contact with the display panel DP. For example, the fingerprint sensing part FS may overlap the opening OP defined in the cover panel CP in a plan view. That is, the fingerprint sensing part FS may be disposed in the opening OP of the cover panel CP, so that a side of the fingerprint sensing part FS may be surrounded by the cover panel CP in a plan view. As a result, the fingerprint sensing part FS may be protected from external impact, noise signals, etc.

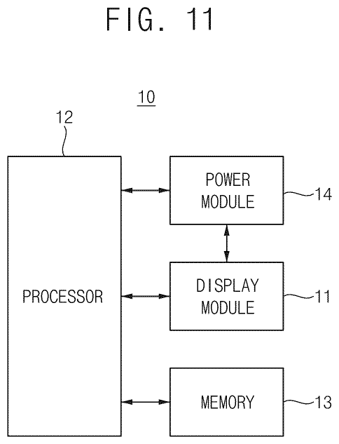

FIG. 11 is a block-diagram showing an electronic device according to an embodiment of the present disclosure.

Referring to FIGS. 1 and 11, the display device DD according to the embodiments may be applied to various electronic devices 10. The electronic device 10 according to an embodiment includes the display device DD described above, and may further include a module or device having additional functions in addition to the display device DD.

The electronic device 10 may include a display module 11, a processor 12, a memory 13, and a power module 14.

The processor 12 may include at least one of a central processing unit (CPU), an application processor (AP), a graphic processing unit (GPU), a communication processor CP, an image signal processor (ISP), and a controller.

The memory 13 may store data information for the operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may convert a power supply module such as a power adapter or a battery device and the power supplied by the power supply module. Specifically, the power module 14 may include a power conversion module that generates power for the operation of the electronic device 10.

At least one of the components of the electronic device 10 described above may be included in the display device according to the embodiments described above. In addition, some of the individual modules functionally included in one module may be included in the display device, and others may be provided separately from the display device. For example, the display device DD may include the display module 11, and the processor 12, the memory 13, and the power module 14 may be provided in the form of other devices within the electronic device 10 other than the display device DD.

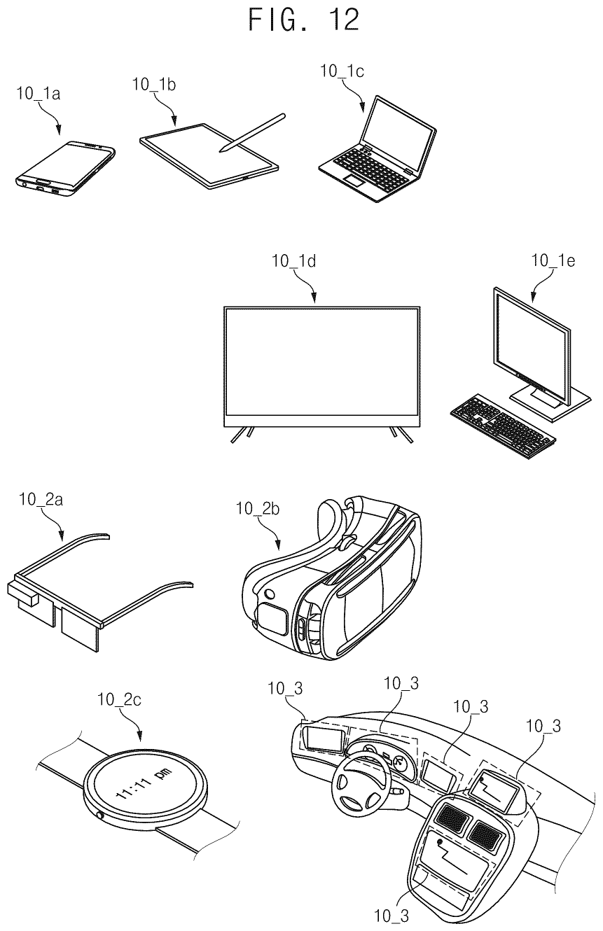

FIG. 12 is schematic views of the electronic devices according to various embodiments of FIG. 11.

Referring to FIGS. 11 and 12, various electronic devices 10 to which the display device DD according to the embodiments is applied may include electronic devices for displaying images, such as a smart phone 10_1a, a tablet PC 10_1b, a laptop 10_1c, a TV 10_1d, and a desk monitor 10_1e. In addition, it may include wearable electronic devices including display modules such as smart glasses 10_2a, head mounted displays 10_2b, smart watches 10_2c, and vehicle electronic devices 10_3 including display modules such as CID (Center Information Display) and room mirror displays disposed on the instrument panel, center fascia, and dashboard of a car.

However, this is exemplary, and the electronic device 10 according to embodiments of the present disclosure is not necessarily limited thereto. For example, the electronic device 10 may be implemented as a mobile phone, a video phone, a smart pad, a smart watch, a tablet PC, a vehicle display, a computer monitor, a notebook, a head mounted display device, etc. In addition, the electronic device 10 may be a television, a monitor, a notebook computer, or a tablet. In addition, the electronic device 10 may be a car.

While the disclosure has been particularly shown and described with reference to embodiments thereof, it will be understood by those of ordinary skill in the art that various changes in form and details may be made therein without departing from the spirit or scope of the disclosure as defined by the following claims.

What is claimed is:

1. A display device comprising:
a display panel including:
a display area in which a plurality of pixels is disposed; and
a peripheral area surrounding at least a portion of the display area and including a pad area spaced apart from one side of the display area in a first direction;
a circuit board disposed under the display panel and including:
a first area including a step portion; and
a second area spaced apart from the first area in a direction opposite to a second direction intersecting the first direction and including a ground portion;
a cover member covering the first area and the second area of the circuit board; and
a fingerprint sensing module disposed under the cover member, contacting the cover member, and including a shield-can overlapping the first area of the circuit board in a plan view.

2. The display device of claim 1, wherein the cover member includes:
a body portion;
a first protrusion protruding from the body portion in a direction opposite to the first direction; and
a second protrusion protruding from the body portion in a direction opposite to the first direction and spaced apart from the first protrusion in a direction opposite to the second direction.

3. The display device of claim 2, wherein the first protrusion of the cover member overlaps the first area in the plan view, and
the second protrusion of the cover member overlaps the second area in the plan view.

4. The display device of claim 2, the fingerprint sensing module further includes:
a fingerprint sensing part configured to detect a user's fingerprint;
a sensing driving element configured to transmit a signal transmitted from the fingerprint sensing part to the circuit board; and
a sensing circuit film configured to connect the fingerprint sensing part and the sensing driving element.

5. The display device of claim 4, wherein the display area of the display panel includes a fingerprint sensing area where the user's fingerprint contacts.

6. The display device of claim 5, wherein the fingerprint sensing part overlaps the fingerprint sensing area of the display panel in the plan view.

7. The display device of claim 5, further comprising:
a cover panel disposed under the display panel.

8. The display device of claim 7, wherein the fingerprint sensing module is disposed under the cover panel in a cross-sectional view.

9. The display device of claim 7, wherein an opening is defined in the cover panel and at least partially overlaps the fingerprint sensing area in the plan view.

10. The display device of claim 7, wherein the fingerprint sensing part of the fingerprint sensing module overlaps an opening of the cover panel in the plan view.

11. The display device of claim 4, wherein the sensing driving element overlaps the first area of the circuit board in the plan view.

12. The display device of claim 4, wherein the shield-can covers the sensing driving element of the fingerprint sensing module, the shield-can is not directly attached to the step portion, and the first protrusion is disposed between the shield-can and the step portion.

13. The display device of claim 4, further comprising:
an adhesive member disposed between the first protrusion of the cover member and the sensing driving element of the fingerprint sensing module.

14. The display device of claim 1, further comprising:
a display driving chip disposed in the pad area of the display panel, and
wherein the cover member covers the display driving chip.

15. The display device of claim 1, wherein the circuit board is electrically connected to the cover member.

16. The display device of claim 1, further comprising:
a connection circuit board disposed in the pad area of the display panel, and
wherein the connection circuit board connects the display panel and the circuit board.

17. The display device of claim 16, wherein the connecting circuit board is bent around a bending axis extending parallel to the second direction.

18. The display device of claim 1, wherein the cover member includes:
a first insulating layer;
a conductive layer disposed on the first insulating layer; and
a second insulating layer disposed on the conductive layer.

19. A display device comprising:
a display panel including:
a display area in which a plurality of pixels is disposed; and
a peripheral area surrounding at least a part of the display area and including a pad area spaced apart from one side of the display area in a first direction;
a circuit board disposed under the display panel, including:
a first area including a step portion; and
a second area spaced apart from the first area in a direction opposite to a second direction intersecting the first direction and including a ground portion; and
a cover member covering the first area and the second area and including:
a body portion;
a first protrusion protruding from the body portion in a direction opposite to the first direction; and
a second protrusion protruding from the body portion in the direction opposite to the first direction and spaced apart from the first area in a direction opposite to the second direction.

20. An electronic device comprising:
a display device; and
a processor configured to drive the display device, and
wherein the display device includes:
a display panel including:
a display area in which a plurality of pixels is disposed; and
a peripheral area surrounding at least a portion of the display area and including a pad area spaced apart from one side of the display area in a first direction;
a circuit board disposed under the display panel and including:
a first area including a step portion; and
a second area spaced apart from the first area in a direction opposite to a second direction intersecting the first direction and including a ground portion;
a cover member covering the first area and the second area of the circuit board; and
a fingerprint sensing module disposed under the cover member, contacting the cover member, and including a shield-can overlapping the first area of the circuit board in a plan view.
